(19) United States
(12) Patent Application Publication
(10) Pub. No.: US 2010/0006843 A1
(43) Pub. Date: Jan. 14, 2010

(54) Polysilsesquioxane copolymer, polysilsesquioxane copolymer thin film including the same, organic light emitting diode display device including the same, and associated methods

(76) Inventors: Sun-Young Lee, Yongin-City (KR); Jong-Hyuk Lee, Yongin-City (KR); Yoon-Hyeung Cho, Yongin-City (KR); Min-Ho Oh, Yongin-City (KR); Byoung-Duk Lee, Yongin-City (KR); So-Young Lee, Yongin-City (KR); Won-Jong Kim, Yongin-City (KR); Yong-Tak Kim, Yongin-City (KR); Jin-Baek Choi, Yongin-City (KR); Do-Yeung Yoon, Seoul (KR)

Correspondence Address: LEE & MORSE, P.C., 3141 FAIRVIEW PARK DRIVE, SUITE 500, FALLS CHURCH, VA, 22042, US

(21) Appl. No.: 12/458,326

(22) Filed: Jul. 8, 2009

(30) Foreign Application Priority Data
Jul. 9, 2008 (KR) 10-2008-0066721

(51) Int. Cl. H01L 33/00; C08G 77/04; G03F 7/075

(52) U.S. Cl. 257/59; 528/34; 430/270.1; 257/E33.053

(57) ABSTRACT

A polysilsesquioxane copolymer, a polysilsesquioxane copolymer including the same, an organic light emitting diode display including the same, and associated methods, the polysilsesquioxane copolymer including a copolymer including repeating units derived from a first monomer selected from the group consisting of alkoxyphenyltrialkoxysilane, alkoxyphenylalkyltrialkoxysilane, alkoxycarbonylphenyltrialkoxysilane, and alkoxycarbonylphenylalkyltrialkoxysilane, and repeating units derived from a second monomer including an α,ω-bis(trialkoxysilyl) compound monomer.

### BACKGROUND

1. Field

Embodiments relate to a polysilsesquioxane copolymer, a polysilsesquioxane copolymer thin film including the same, an organic light emitting diode (OLED) display device including the same, and associated methods.

2. Description of the Related Art

In general, a planarization layer formed of an acrylic material may be disposed on source and drain electrodes of a thin film transistor (TFT) to protect the source and drain electrodes during a process of fabricating, e.g., OLED display devices. However, the planarization layer formed of the acrylic material may not completely protect the electrodes, since it may have a low hardness. An additional inorganic silicon nitride layer may then be deposited between the electrodes and the planarization layer formed of the acrylic material, which may make the process more complicated and costly.

Attempts have been made to use a layer (e.g., silicon-on-glass (SOG)) formed of silicon having good strength and temperature properties instead of the organic acrylic layer. However, the typical SOG may not allow a direct photo-patterning process. Accordingly, in order to form patterns using a photolithography process, an additional photoresist (PR) may be applied, which may then be exposed and developed to form a PR pattern. The SOG may be, e.g., dry-etched or wet-etched using the PR pattern as a mask to thereby form the patterns.

However, the method of forming patterns using PR as mentioned above may be accompanied by complicated processes including, e.g., a PR coating process, an exposure process, a development process, a stripping process, etc., which may complicate the process and decrease the manufacturing yield.

### SUMMARY

Embodiments are therefore directed to a polysilsesquioxane copolymer, a polysilsesquioxane copolymer thin film including the same, an organic light emitting diode (OLED) display device including the same, and associated methods, which substantially overcome one or more of the problems due to the limitations and disadvantages of the related art.

It is therefore a feature of an embodiment to provide a polysilsesquioxane copolymer thin film including having good mechanical strength and planarization performance.

It is therefore another feature of an embodiment to provide a polysilsesquioxane copolymer that enables fabrication of a thin film allowing positive tone patterning to be achieved by directly irradiating light without using a photoresist.

At least one of the above and other features and advantages may be realized by providing a polysilsesquioxane copolymer including a copolymer including repeating units derived from a first monomer selected from the group consisting of compounds represented by Chemical Formulae 1 to 4:

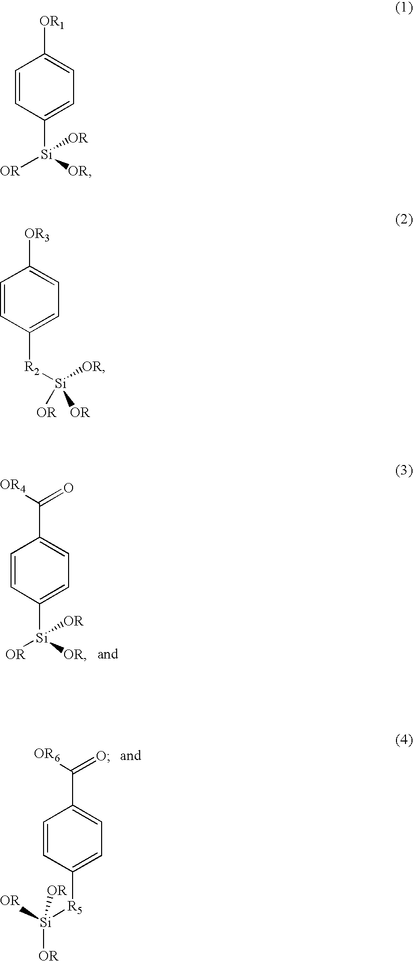

repeating units derived from a second monomer including an α,ω-bis(trialkoxysilyl) compound monomer represented by Chemical Formula 5:

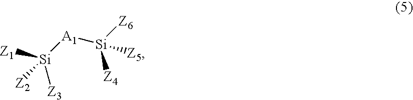

wherein in Chemical Formulae 1 to 4, R, R₁, R₂, R₃, R₄, R₅, and R₆ are each independently a substituted or unsubstituted C₁ to C₃₀ alkyl group, and in Chemical Formula 5, Z₁, Z₂, Z₃, Z₄, Z₅, and Z₆ are each independently a hydroxy group, a substituted or unsubstituted C₁ to C₃₀ alkyl group, or a substituted or unsubstituted C₁ to C₃₀ alkoxy group, and A₁ is a substituted or unsubstituted C₁ to C₃₀ alkyl residue.

The copolymer may further include repeating units derived from a third monomer selected from the group consisting of compounds represented by General Formula 1: (R₇O)₃—Si—C₆H₄—(C(R₈)₂)ₙ—OH, and General Formula 2: (R₇O)₃—Si—C₆H₄—(C(R₈)₂)ₙ—COOH, wherein, in General Formulae 1 and 2, R₇ and R₈ are each independently a hydrogen or alkyl group, and n is 0 to 10.

The polysilsesquioxane copolymer may have a weight average molecular weight of about 900 to about 30000.

The repeating units derived from the third monomer may be included in a molar ratio of greater than 0 to about 50% based on the total moles of the first monomer and the second monomer repeating units.

The polysilsesquioxane copolymer may have a weight average molecular weight of about 900 to about 30000.

The repeating units derived from the first monomer and the repeating units derived from the second monomer may be included in a molar ratio of about 50 to less than 100% of the first monomer repeating units:greater than 0 to less than about 50% of the second monomer repeating units.

At least one of the above and other features and advantages may also be realized by providing a polysilsesquioxane copolymer thin film including a photoacid generator, and the polysilsesquioxane copolymer.

The photoacid generator may include at least one of arylbis(trichloromethyl)triazine and enferfluorobutane sulfonyl naphthalenin imide.

The photoacid generator may be included in an amount of about 1 to about 30 wt % based on the total weight of the polysilsesquioxane copolymer and the photoacid generator.

Portions of the thin film exposed to UV light may be soluble in a developing solution of tetramethylammonium hydroxide (TMAH).

At least one of the above and other features and advantages may also be realized by providing an organic light emitting diode display device including a substrate, a thin film transistor (TFT) disposed on the substrate and including a semiconductor layer, a gate electrode, a gate insulating layer, and source and drain electrodes, a planarization layer disposed on the TFT, and an organic light emitting diode disposed on the planarization layer and including a first electrode electrically connected to the source or drain electrode, an organic layer having an emitting layer, and a second electrode, wherein the planarization layer includes the polysilsesquioxane copolymer thin film.

At least one of the above and other features and advantages may also be realized by providing a polysilsesquioxane copolymer thin film, including a photoacid generator, and the polysilsesquioxane copolymer.

The photoacid generator may be included in an amount of about 1 to about 30 wt % based on the total weight of the polysilsesquioxane copolymer and the photoacid generator.

Portions of the thin film exposed to UV light may be soluble in a developing solution of tetramethylammonium hydroxide (TMAH).

The photoacid generator may include at least one of arylbis(trichloromethyl)triazine and enferfluorobutane sulfonyl naphthalenin imide.

At least one of the above and other features and advantages may also be realized by providing an organic light emitting diode display device including a substrate, a thin film transistor (TFT) disposed on the substrate and including a semiconductor layer, a gate electrode, a gate insulating layer and source and drain electrodes, a planarization layer disposed on the TFT, and an organic light emitting diode disposed on the planarization layer and including a first electrode electrically connected to the source or drain electrode, an organic layer having an emitting layer, and a second electrode, wherein the planarization layer includes the polysilsesquioxane copolymer thin film.

At least one of the above and other features and advantages may also be realized by providing a method of fabricating a polysilsesquioxane copolymer, including copolymerizing, using an acid or base catalyst in a mixed solvent including an organic solvent and water, a first monomer selected from the group consisting of compounds represented by Chemical Formulae 1 to 4:

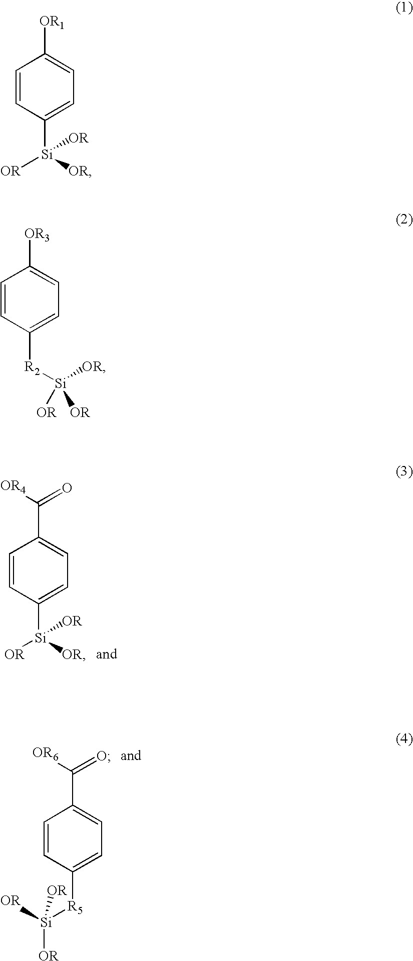

a second monomer including an α,ω-bis(trialkoxysilyl) compound monomer represented by Chemical Formula 5:

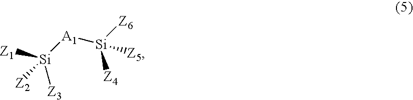

wherein in Chemical Formulae 1 to 4, R, R₁, R₂, R₃, R₄, R₅, and R₆ are each independently a substituted or unsubstituted C₁ to C₃₀ alkyl group, and in Chemical Formula 5, Z₁, Z₂, Z₃, Z₄, Z₅, and Z₆ are each independently a hydroxy group, a substituted or unsubstituted C₁ to C₃₀ alkyl group, or a substituted or unsubstituted C₁ to C₃₀ alkoxy group, and A₁ is a substituted or unsubstituted C₁ to C₃₀ alkyl residue.

The first monomer and the second monomer may be included in a molar ratio of about 50 to less than 100% of the first monomer:greater than 0 to less than about 50% of the second monomer.

The method may further include copolymerizing a third monomer selected from the group consisting of compounds represented by General Formula 1: (R₇O)₃—Si—C₆H₄—(C(R₈)₂)ₙ—OH, and General Formula 2: (R₇O)₃—Si—C₆H₄—(C(R₈)₂)ₙ—COOH, wherein, in General Formulae 1 and 2, R₇ and R₈ are each independently a hydrogen or alkyl group, and n is 0 to 10.

The third monomer may be included a molar ratio of greater than 0 to about 50% based on the total moles of the first monomer and the second monomer.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A to 1C illustrate cross-sectional views of a process of fabricating an OLED display device including a polysilsesquioxane copolymer thin film according to an embodiment;

FIGS. 2A and 2B illustrate Atomic Force Microscope (AFM) images of a thin film according to Synthesis Examples 8 and 11 of Experimental Example 2;

FIG. 3 illustrates an AFM image of a thin film according to Synthesis Example 15 of Experimental Example 4;

FIGS. 4A to 4C illustrate pictures of positive-tone patterned thin films according to Experimental Example 4;

FIG. 5 illustrates an AFM image of a thin film according to Experimental Example 5;

FIGS. 6A and 6B illustrate pictures of positive-tone patterned thin films according to Experimental Example 5;

FIG. 7 illustrates Table 1 showing composition, reaction times, and weight average molecular weights for Synthesis Examples 1 to 5;

FIG. 8 illustrates Table 2 showing composition, reaction times, and weight average molecular weights for Synthesis Examples 6 to 12; and

FIG. 9 illustrates Table 3 showing composition, number average molecular weight, and weight average molecular weight for Synthesis Examples 13 to 15.

### DETAILED DESCRIPTION

Korean Patent Application No. 10-2008-0066721, filed on Jul. 9, 2008, in the Korean Intellectual Property Office, and entitled: “Polysilsesquioxane Copolymer, Fabrication Method for the Same, Polysilsesquioxane Copolymer Thin Film Using the Same, and Organic Light Emitting Diode Display Device Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

### First Embodiment: Fabrication of Polysilsesquioxane Copolymer

1. Fabrication of Polysilsesquioxane Bipolymer

A first monomer selected from the group consisting of alkoxyphenyltrialkoxysilane represented by Chemical Formula 1:

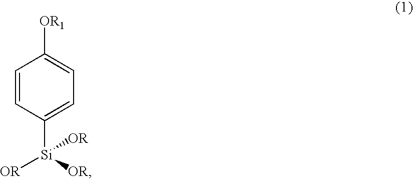

alkoxyphenylalkyltrialkoxysilane represented by Chemical Formula 2:

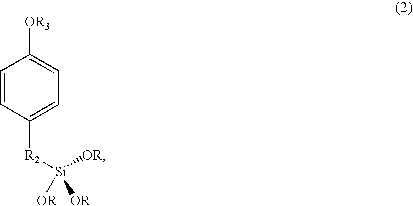

alkoxycarbonylphenyltrialkoxysilane represented by Chemical Formula 3:

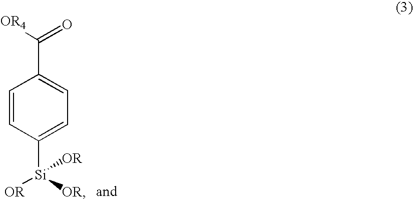

alkoxycarbonylphenylalkyltrialkoxysilane represented by Chemical Formula 4:

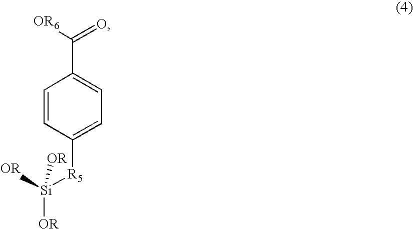

may be added to a reaction vessel having a refluxing device along with a second monomer including an α,ω-bis(trialkoxysilyl) compound monomer, i.e., having reaction sites at both ends, represented by Chemical Formula 5:

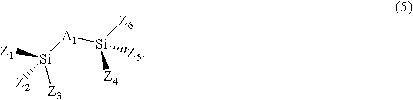

In Chemical Formulae 1 to 4, R, R₁, R₂, R₃, R₄, R₅, and R₆ may each independently be a substituted or unsubstituted C₁ to C₃₀ alkyl group. In Chemical Formula 5, Z₁, Z₂, Z₃, Z₄, Z₅, and Z₆ may each independently be a hydroxy group, a substituted or unsubstituted C₁ to C₃₀ alkyl group, or a substituted or unsubstituted C₁ to C₃₀ alkoxy group, and A₁ may be a substituted or unsubstituted C₁ to C₃₀ alkyl residue. The chirality of the compounds represented by Chemical Formulae 1 to 5 is not limited.

A molar ratio of the first monomer:the second monomer may be about 50 to less than about 100% of the first monomer:greater than 0 to about 50% of the second monomer.

The second monomer may have more reactive functional groups compared to the first monomer, and thus may have a high crosslinking density during a copolymerization reaction in the presence of water, as described below. Therefore, when the copolymerization is performed using a second monomer represented by Chemical Formula 5, the molecular weight of a polymer may rapidly increase during sol-gel polymerization using an acid or base catalyst. In addition, an inter-molecular condensation speed may increase in comparison with an intra-molecular condensation reaction that may frequently occur when a monomer represented by Chemical Formulae 1 to 4 is homopolymerized. Accordingly, when the second monomer is included during forming of the polysilsesquioxane copolymer, undesirable formation of ring-shaped silsesquioxane having a low molecular weight may be decreased, and the polysilsesquioxane copolymer being formed may have an amorphous structure. Consequently, a layer fabricated using the polysilsesquioxane copolymer may advantageously have high density and mechanical strength.

An organic solvent may then be added to the reaction vessel. The organic solvent may be added in an amount such that a total monomer concentration including the first monomer and the second monomer is about 25 wt % to about 35 wt % based on the total weight of the solvent and monomers. The organic solvent may include, e.g., methylisobutylketone, acetone, chloroform, tetrahydrofuran (THF), toluene, propylene glycol methyl ether acetate (PM acetate) and/or alcohol.

Water and a catalyst may then be added to the reaction vessel. The water may be added in a molar ratio of about 1 to about 10, per 1 mole of the total monomer content.

The catalyst may be an acid catalyst or a base catalyst. The acid catalyst may include, e.g., hydrochloric acid (HCl) or sulfuric acid (H₂SO₄), and the base catalyst may include, e.g., potassium hydroxide (KOH) or tetrabutylammonium hydroxide ([CH₃(CH₂)₃]₄NOH). The catalyst may be added in a molar ratio of about 0.01 to about 0.1 mol per 1 mol of the total monomer content. The catalyst is preferably a base catalyst, since a weight average molecular weight (M_{w}) of the copolymer may be increased by a large amount relative to reaction time, and a layer fabricated using the copolymer may have good thermal stability and mechanical strength, compared to a layer formed using the acid catalyst. In addition, the polysilsesquioxane copolymer fabricated using the base catalyst may be highly soluble in organic solvent but not in water.

Then, the reaction vessel including the materials mentioned above may be subjected to reaction for about 6 to about 24 hours at about 80° C. When the polysilsesquioxane copolymer of an embodiment is formed, a ratio of the monomers, a reaction temperature, a reaction time, and an amount of catalyst may be adjusted to adjust the amount of Si—OH end groups and molecular weight. The molecular weight may be adjusted depending on the amount of the Si—OH end groups, and particularly, M_{w} is preferably about 900 to about 30000. The amount of Si—OH end groups is preferably about 0 to about 50%. Maintaining the M_{w} at about 900 to about 30000 and the amount of the Si—OH end groups at about 0 to about 50%, may help ensure that the polysilsesquioxane copolymer is highly soluble in a developing solution when the thin film formed using the polysilsesquioxane copolymer is irradiated with light to carry out positive-tone patterning.

2. Fabrication of Polysilsesquioxane Terpolymer

A third monomer may be further included with the first and second monomers. The third monomer may be represented by General Formula 1: (R₇O)₃—Si—C₆H₄—(C(R₈)₂)ₙ—OH or General Formula 2: (R₇O)₃—Si—C₆H₄—(C(R₈)₂)ₙ—COOH. The third monomer may have a polar functional group to improve adhesion of a layer fabricated using the polysilsesquioxane copolymer described above. R₇ and R₈ of General Formulae 1 and 2 may each independently be a hydrogen or alkyl group, and n may be about 0 to about 10. The third monomer having the polar functional group may be added in a molar ratio of about 0 to about 50 wt % based on the total moles of the first monomer and the second monomer.

An organic solvent may then be added to the reaction vessel including the first, second, and third monomers. The organic solvent may be added in an amount such that a total monomer concentration is about 25 wt % to about 35 wt % based on the total weight of the solvent and the monomers.

Water and the catalyst may then be added to the reaction vessel. The water may be added in a molar ratio of about 1 to about 10 mol, per 1 mole of the total monomers. The catalyst may be added in a molar ratio of about 0.01 to about 0.1 mol, per 1 mol of the total monomers.

Then, the reaction vessel including the water and catalyst may be subjected to reaction for about 6 to about 24 hours at about room temperature to about 80° C. When the polysilsesquioxane copolymer of the embodiment is formed, a ratio of the monomers, a reaction temperature, a reaction time, and an amount of catalyst may be adjusted to adjust the amount of Si—OH end groups and molecular weight. The molecular weight may be adjusted depending on the amount of the Si—OH end groups, and particularly, M_{w} is preferably about 900 to about 30000. The amount of the Si—OH end groups is preferably about 0 to about 50%. Maintaining the M_{w} at about 900 to about 30000 and the amount of the Si—OH end groups at about 0 to about 50% may help ensure that the polysilsesquioxane copolymer is highly soluble in a developing solution when carrying out positive-tone patterning by irradiating light to the thin film formed using the polysilsesquioxane copolymer.

### Second Embodiment: Fabrication of Polysilsesquioxane Copolymer Thin Film

The polysilsesquioxane copolymer thin film according to an embodiment may be fabricated by mixing the polysilsesquioxane copolymer fabricated according to the above embodiments with a photoacid generator and an organic solvent, and coating the mixture on a substrate.

The photoacid generator may include, e.g., Ciba IRGACURE 1XX series made by Ciba Co., arylbis(trichloromethyl)triazine or en-perfluorobutane sulfonyl naphthalenin imide. The photoacid generator may be included in an amount of about 1 to about 30 wt % based on the total weight of the photoacid generator and polysilsesquioxane copolymer. The photoacid generator is preferably mixed while visible light is blocked therefrom.

The organic solvent may include, e.g., methylisobutylketone, acetone, chloroform, THF, toluene, PM acetate, and/or alcohol. The organic solvent may be included in an amount of about 10 to about 30 wt % based on the total weight of the photoacid generator and polysilsesquioxane copolymer. Dissolution of the photoacid generator and polysilsesquioxane copolymer in the organic solvent may be performed at about room temperature.

The solution fabricated by mixing the polysilsesquioxane copolymer, the photoacid generator and the organic solvent may then be spin-coated on a substrate. The coated substrate may then be baked for about 1 to about 3 minutes at about 100 to about 130° C., thereby fabricating a polysilsesquioxane copolymer thin film.

A polysilsesquioxane copolymer thin film of an embodiment was measured using an Atomic Force Microscope (AFM) to have roughness values of about 1 nm or less, and may be capable of ensuring a flatness of about 95% or more. In addition, hardness of the thin film was measured using a nanoindenter to have a good hardness of about 1 GPa or more and strong resistance to scratches resulting from external impacts.

Patterning of Polysilsesquioxane Copolymer Thin Film

An exposure process may be performed by irradiating light onto the polysilsesquioxane copolymer thin film of an embodiment. The exposure process may irradiate ultraviolet (UV) light having a center wavelength of about 240 to about 450 nm for about 1 to about 5 minutes. Then, the polysilsesquioxane copolymer thin film may be baked for about 1 to about 3 minutes at about 100 to about 130° C. The thin film may then be developed by a developing solution. The developing solution may include, e.g., tetramethylammonium hydroxide (TMAH).

When light is irradiated on the thin film, the photoacid generator included in the thin film may cause an acid to be generated. This generated acid may cause an alkoxy group or an alkoxycarbonyl group of phenyl derivatives of the copolymer to be changed to a hydroxy group or a carboxylic acid group, so that the exposed portions of the copolymer become soluble in the developing solution. Accordingly, when the thin film that has been irradiated with light is developed, the portion where the light has been irradiated may be removed to enable positive-tone patterning. Then, the thin film may be rinsed in DI water and cured for about 30 to about 60 minutes at about 220 to about 240° C.

Fabrication of OLED Display Device Including Polysilsesquioxane Copolymer Thin Film

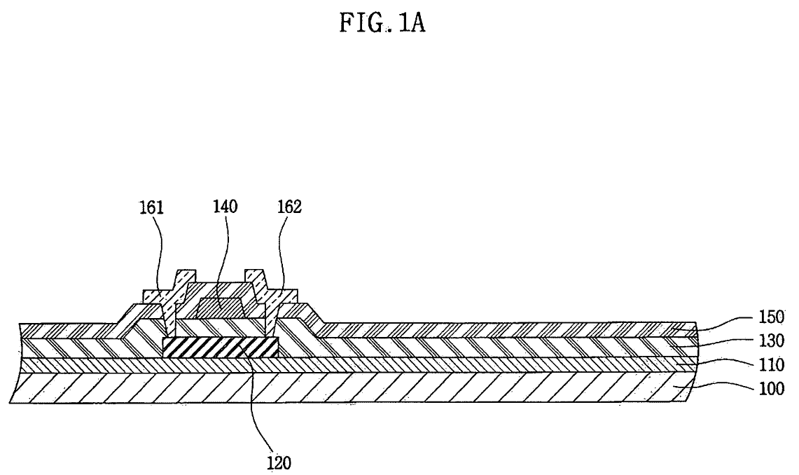

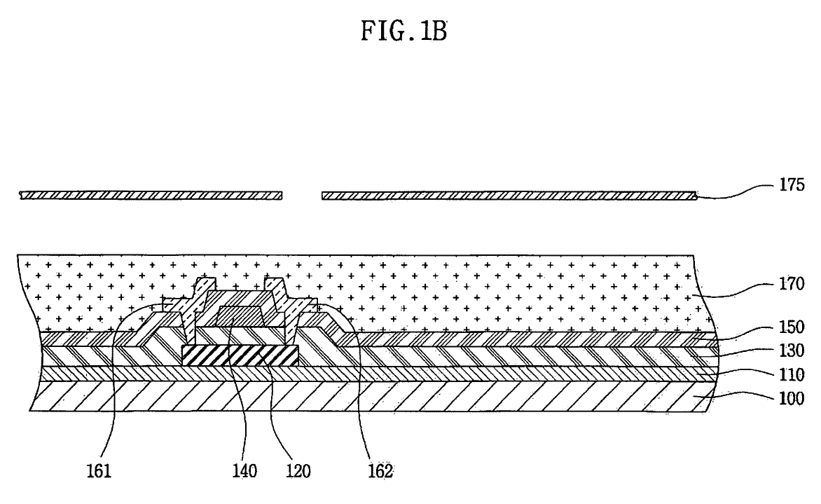

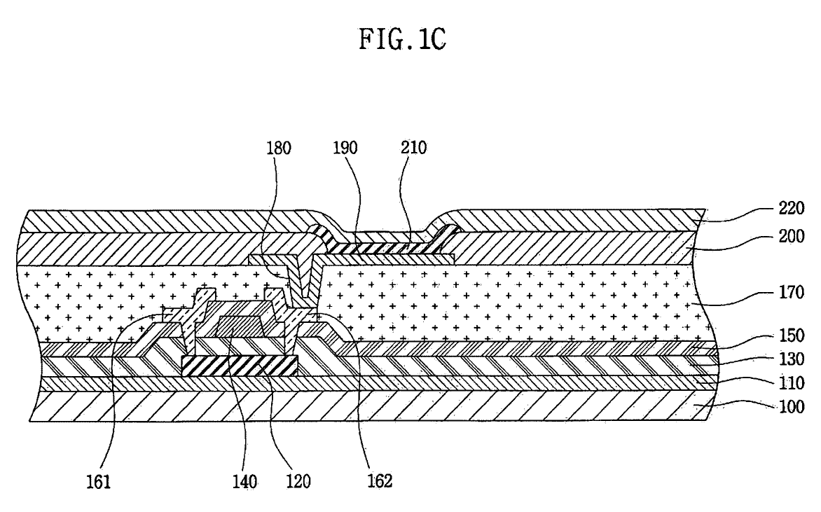

FIGS. 1A to 1C illustrate cross-sectional views of a process of fabricating an OLED display device including the polysilsesquioxane copolymer thin film of an embodiment. Referring to FIG. 1A, a buffer layer 110 may be formed on a transparent substrate 100 including, e.g., insulating glass or plastic. The buffer layer 110 may act to facilitate crystallization of a polycrystalline silicon layer (to be formed in a subsequent process), by preventing out-diffusion of moisture or impurities from the substrate 100, or by adjusting a heat transfer rate at the time of crystallization. The buffer layer 110 may be formed of, e.g., a silicon oxide layer, a silicon nitride layer, or a multi layer thereof.

An amorphous silicon layer may then be formed on the buffer layer 110 using a deposition method, e.g., Plasma Enhanced Chemical Vapor Deposition (PECVD) or Low Pressure CVD (LPCVD), and may be crystallized and patterned to form a polycrystalline semiconductor layer 120. The method of crystallizing the amorphous silicon layer may include, e.g., Solid Phase Crystallization (SPC), Sequential Lateral Solidification (SLS), Excimer Laser Annealing (ELA), Metal Induced Crystallization (MIC), Metal Induced Lateral Crystallization (MILC), or Super Grain Silicon (SGS).

A gate insulating layer 130 may then be formed on the entire surface of the substrate 100. The gate insulating layer 130 may include, e.g., a silicon oxide layer, a silicon nitride layer, or a double layer thereof.

A gate electrode 140 may then be formed on a region corresponding to the channel region of the semiconductor layer 120. The gate electrode 140 may be formed of a single layer, e.g., an aluminum (Al) layer or an Al alloy layer of aluminum-neodymium (Al—Nd), or a multi layer where, e.g., an Al alloy layer is stacked on a chromium (Cr) or molybdenum (Mo) alloy layer. An interlayer insulating layer 150 may then be formed on the entire surface of the substrate 100 including the gate electrode 140.

Predetermined regions of the interlayer insulating layer 150 and the gate insulating layer 130 may then be etched to form a contact hole. Source and drain electrodes 161 and 162 may be formed to be electrically connected to the source and drain regions of the semiconductor layer 120 through the contact hole.

Referring to FIG. 1B, a planarization layer 170 may then be formed on the entire surface of the substrate 100. In the present embodiment, the planarization layer 170 may be formed by mixing a photoacid generator and an organic solvent with the polysilsesquioxane copolymer of an embodiment and by spin-coating on the substrate 100.

A via hole may then be formed in the planarization layer 170 to expose at least a portion of the source or drain electrode. Typically, a via hole may be formed by forming a PR pattern on a general planarization layer and performing a photolithography process using the same. However, according to the present embodiment, the PR pattern may be omitted, and the via hole may be formed by directly irradiating light onto the planarization layer 170 formed of the thin film using the polysilsesquioxane copolymer of an embodiment, and developing the planarization layer. In detail, after a mask 175 is disposed on the planarization layer 170 so as to directly irradiate light onto a position where the via hole is to be formed, the planarization layer 170 may be irradiated with light, developed by a developing solution, and rinsed in DI water.

Referring to FIG. 1C, when the planarization layer 170 is developed, some of the planarization layer 170 where the light is irradiated may be removed to form a via hole 180 in the planarization layer 170. Therefore, according to the embodiment, the via hole 180 may be formed by exposure and development processes directly on the planarization layer 170, without using a PR for patterning, thereby simplifying the process.

The thin film using the polysilsesquioxane copolymer of an embodiment may allow positive-tone patterning to be carried out, so that a portion where the via hole 180 is formed in the planarization layer 170 may have a forward-tapered shape. When the planarization layer 170 has a forward-tapered shape in the portion where the via hole 180 is formed, a short circuit may be prevented on a first electrode in the via hole 180 when forming the first electrode in a subsequent process. In addition, the via hole 180 may be formed by positive-tone patterning, so that processing time and a failure rate may be decreased due to decreased exposure area, when compared to negative-tone patterning.

In addition, as described above, the thin film using the polysilsesquioxane copolymer of an embodiment may have a roughness of about 1 nm or less, and may ensure a good hardness of about 1 GPa or more. Accordingly, when the planarization layer 170 is formed of the thin film using the polysilsesquioxane copolymer of an embodiment, the source and drain electrodes 161 and 162 below the planarization layer may be effectively protected, and planarization requirements may also be satisfied.

A first electrode 190 connected to one of the source and drain electrodes 161 and 162 may then be formed on the planarization layer 170. The first electrode 190 may be disposed within the via hole 180. Thus, the first electrode 190 may be in contact with one of the source and drain electrodes 161 and 162 exposed by the via hole 180, and may extend onto the planarization layer 170. The first electrode 190 may be an anode, and may include, e.g., Indium Tin Oxide (ITO) or Indium Zinc Oxide (IZO).

A pixel defining layer 200, where an opening exposing a predetermined region of the first electrode 190 is formed, may then be formed on the first electrode 190. The pixel defining layer 200 may be formed of, e.g., an organic layer or an inorganic layer.

An organic layer 210 may then be formed on the first electrode 190 exposed through the opening. The organic layer 210 may include an emitting layer. The organic layer 210 may also include, e.g., a hole injecting layer, a hole transporting layer, a hole blocking layer, an electron transporting layer, an electron injecting layer, and an electron blocking layer.

A second electrode 220 may then be formed on the entire surface of the substrate 100. The second electrode 220 may be a cathode, and may be formed of, e.g., Mg, Ag, Al, Ca, or an alloy thereof, which has a low work function.

In the present embodiment, the planarization layer of the OLED display device has been described using the thin film formed of the polysilsesquioxane copolymer of an embodiment. However, the application of a thin film according to an embodiment is not limited to the planarization layer, and other layers in the OLED display device may also be formed with the thin film.

Experimental Examples will now be described to help understand the embodiments. However, the Experimental Examples below are merely illustrative and do not limit the scope.

### EXPERIMENTAL EXAMPLE 1

### Acid Catalyst

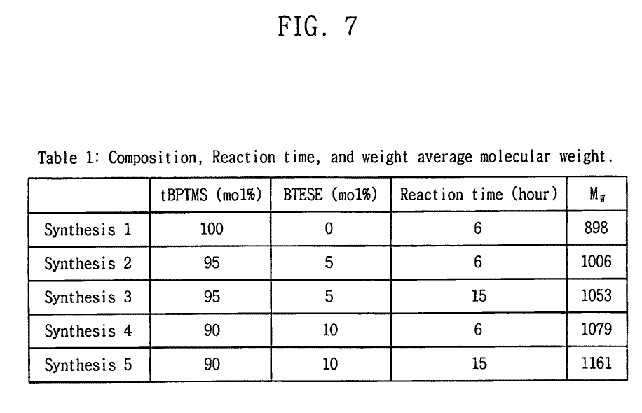

Nitrogen gas was flowed into reaction vessels with a refluxing device to form an atmosphere having a pressure of 1 atm. The first monomer, t-butoxyphenyltrimethoxysilane (tBPTMS), whose R is a methyl group and R₁ is a t-butyl group in Chemical Formula 1, and the second monomer, (bis(triethoxysilyl)ethane: BTESE), whose Z₁ to Z₆ are each an ethoxy group and A₁ is an ethylene group in Chemical Formula 5, were added to the reaction vessels in a molar ratio of 100%:0% (tBPTMS:BTESE) for Synthesis 1, 95%:5% for Syntheses 2 and 3, and 90%:10% for Syntheses 4 and 5. Tetrahydrofuran (THF) as a solvent was then added to each reaction vessel in an amount such that a total concentration of the two monomers was 30 wt % based on the total weight of the solvent and the monomers. A hydrochloric acid solution as an acid catalyst was then added in a 1:0.03 molar ratio of the two monomers to the hydrochloric acid of the hydrochloric acid solution. Water was added in a 1:5 molar ratio of the two monomers to the water and water of the hydrochloric acid solution. The reaction vessels were then subjected to reaction at 60° C. for 6 hours for Syntheses 1, 2, and 4, and 15 hours for Syntheses 3 and 5. All solvents were removed after the reaction to obtain solid-state polysilsesquioxane copolymers. The M_{w} of each of the copolymers was measured and the results are shown in Table 1 of FIG. 7.

Referring to Table 1, it may be seen that copolymerization of the first monomer tBPTMS and the second monomer BTESE of Syntheses 2 to 5 had an increased M_{w} over the homopolymerization of just the first monomer tBPTMS of Synthesis 1. It may also be seen that M_{w} was also increased by a small amount when the BTESE molar ratio was increased as in Syntheses 4 and 5. However, it may also be seen that the change in M_{w} was not great depending on the reaction time in the presence of acid catalyst.

### EXPERIMENTAL EXAMPLE 2

### Base Catalyst

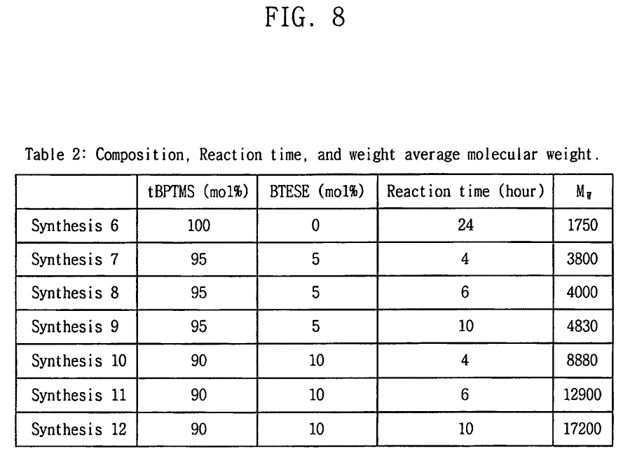

Nitrogen gas was flowed into reaction vessels with a refluxing device to form an atmosphere having a pressure of 1 atm. tBPTMS, whose R is a methyl group and R₁ is a tertbutyl group in Chemical Formula 1, and BTESE, whose Z₁ to Z₆ are each an ethoxy group and A₁ is an ethylene group in Chemical Formula 5, were added to each reaction vessel in a molar ratio of 100%:0% (tBPTMS:BTESE) for Synthesis 6, 95%:5% for Syntheses 7 to 9, and 90%:10% for Syntheses 10 to 12. THF as a solvent was then added to each reaction vessel in an amount such that a total concentration of the two monomers was 30 wt % based on the total weight of the solvent and the monomers. A potassium hydroxide solution as a base catalyst was then added in a 1:0.03 molar ratio of the two monomers to the potassium hydroxide of the potassium hydroxide solution. Water was added in a 1:5 molar ratio of the two monomers to the water and water of the potassium hydroxide solution. The reaction vessels were then subjected to reaction at 60° C. for 4 hours for Syntheses 7 and 10, 6 hours for Syntheses 8 and 11, 10 hours for Syntheses 9 and 12, and 24 hours for Synthesis 6. All solvents were removed after the reaction to obtain solid-state polysilsesquioxane copolymers. The M_{w} of each of the copolymers was measured and the results are shown in Table 2 of FIG. 8.

Referring to Table 2, it may be seen that copolymerization of the first monomer tBPTMS and the second monomer BTESE in Syntheses 7 to 12 had an increased M_{w} over the homopolymerization of just the first monomer tBPTMS of Synthesis 6. It may also be seen that M_{w} was increased by an amount (greater in the presence of the base catalyst than the acid catalyst) when the BTESE molar ratio was increased. However, it may also be seen that the increase in M_{w} was greater when using the base catalyst than when using the acid catalyst (Syntheses 1 to 5) over the increased reaction time. In addition, when tBPTMS and BTESE were copolymerized in the presence of the base catalyst, it may be seen that M_{w} was increased 5 to 10-fold to thereby significantly reduce the reaction time (10 hours or less) in comparison with the homopolymerization of tBPTMS reaction time of 24 hours.

Referring to Tables 1 and 2, it may be seen that the base catalyst is preferable to an acid catalyst during fabrication of the polysilsesquioxane copolymer according to an embodiment.

### EXPERIMENTAL EXAMPLE 3

### Thin Films

A photoacid generator, Ciba IRGACURE 1XX series made by Ciba Co., was added in an amount of 6 wt %, based on the total weight of the copolymer and the photoacid generator, to each of the copolymers fabricated according to Synthesis Examples 8 and 11 of Experimental Example 2. PM acetate as an organic solvent in an amount of 20 wt % based on the total weight of the copolymer and the photoacid generator was injected into the reaction vessels, and then subjected to mixing. After mixing, the solutions were spin-coated on substrates to have a thickness of 750 nm and then baked for 2 minutes at 120° C. Roughness of each of the thin films was measured using the AFM.

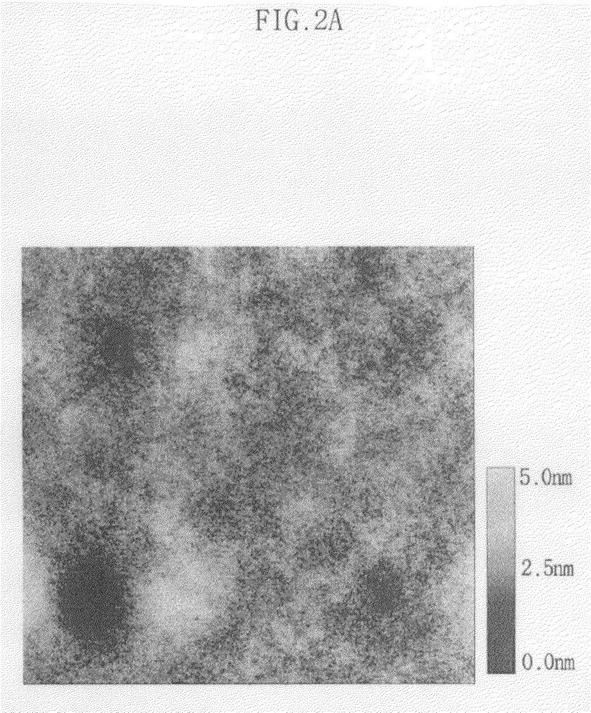

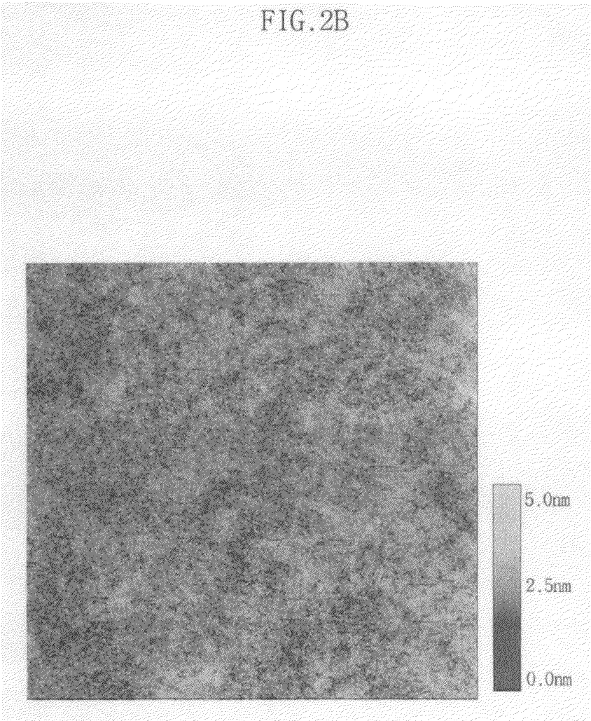

FIGS. 2A and 2B illustrate AFM images of respective thin films. FIG. 2A illustrates the thin film fabricated according to Synthesis Example 8 of Experimental Example 2, and its measured roughness was 0.875 nm. FIG. 2B illustrates the thin film fabricated according to Synthesis Example 11 of Experimental Example 2 and its measured roughness was 0.489 nm. Both roughnesses of the thin films were 1 nm or less, which means that the surface property was good, and a flatness of 95% or more could be ensured. This is substantially the same degree as the flatness of, e.g., a typical acrylic resin, etc. In addition, according to the results mentioned above, it may be seen that the roughness decreases when M_{w} increases.

### EXPERIMENTAL EXAMPLE 4

### Terpolymer 1 and Thin Film

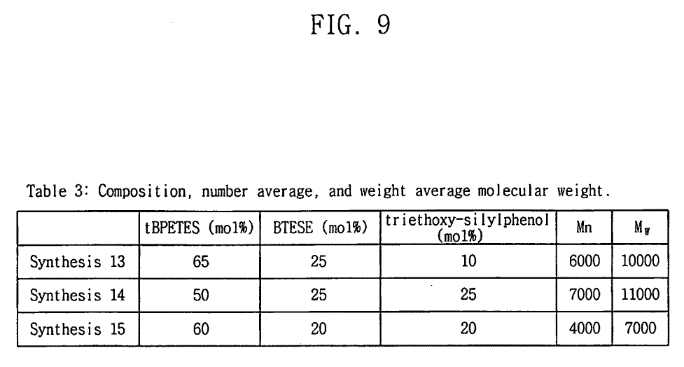

Nitrogen gas was flowed into reaction vessels with a refluxing device to form an atmosphere with a pressure of 1 atm. t-butoxyphenylethyltriethoxysilane (tBPETES), whose R is an ethyl group, R₂ is an ethylene group and R₃ is a t-butyl group in Chemical Formula 2, BTESE, whose Z₁ to Z₆ are each an ethoxy group and A₁ is an ethylene group in Chemical Formula 5, and the third monomer triethoxysilylphenol were added to the reaction vessels in a molar ratio of 50%:25%:25% (tBPETES:BTESE:triethoxysilylphenol) for Synthesis 14, 60%:20%:20% for Synthesis 15, 65%:25%:10% for Synthesis 13, and 40%:30%:30%. THF as a solvent was then added to the vessels in an amount such that the total concentration of the three monomers was 25 wt % based on the total weight of the solvent and the monomers. Tetrabutylammonium hydroxide as a base catalyst was then added in an 1:0.1 molar ratio of the three monomers to the tetrabutylammonium hydroxide. Water was added in an 1:4 molar ratio of the three monomers to the water. The reaction vessels were then subjected to a reaction at 60° C. for 10 hours. All solvents were removed after the reaction to obtain solid-state polysilsesquioxane copolymers. The M_{w} and number average molecular weight (Mn) of each of the copolymers were measured and the results are shown in Table 3 of FIG. 9.

A photoacid generator, Ciba IRGACURE 1XX series made by Ciba Co., was added in an amount of 6 wt % based on the total weight of the copolymer and the photoacid generator to each of the solid-state copolymers. PM acetate as an organic solvent in an amount of 25 wt % based on the total weight of the copolymer and the photoacid generator, was injected into each reaction vessel, which were then subjected to mixing. After mixing, the solutions were spin-coated on substrates at 3000 rpm for 30 seconds to have a thickness of 750 nm, and then baked for 1 minute at 100° C. The roughness of the thin films according to Synthesis Example 15 was measured using the AFM.

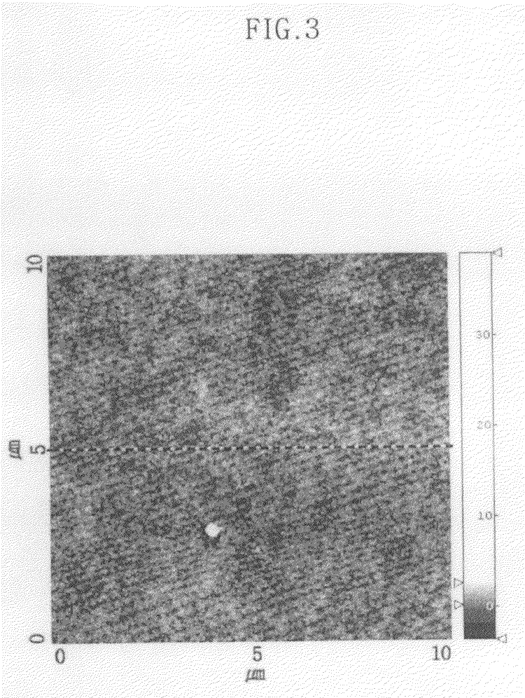

FIG. 3 illustrates an AFM image of the thin film according to Synthesis Example 15. Referring to FIG. 3, the measured roughness of the thin film according to Synthesis Example 15 was 0.06651 nm, which means that the surface property was very good. In addition, in comparison with Experimental Example 2, it may be seen that the roughness of the thin film was improved due to addition of the third monomer. UV rays having center wavelengths of 365 nm and projected in square shapes with 5 μm each side, 10 μm each side, 20 μm each side and 50 μm each side, were irradiated onto respective thin films, and the thin films were exposed to light and baked for 2 minutes at 110° C. The thin films were then developed by being immersed in 2.38 wt % TMAH water solution for 20 seconds, rinsed in DI water for 20 seconds, and cured for 60 minutes at 230° C.

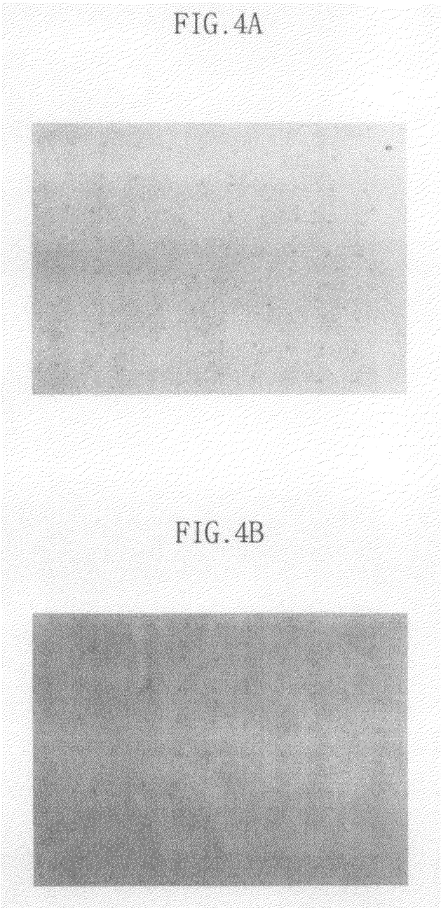

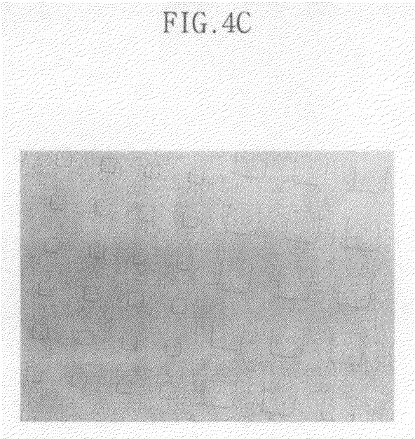

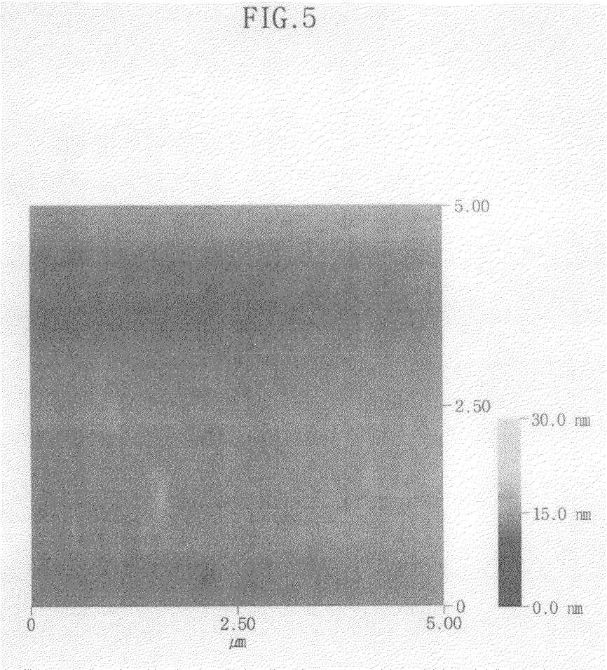

FIGS. 4A to 4C illustrate pictures of the positive-tone patterned thin films. Referring to FIGS. 4A to 4C, it may be seen that regions where the laser was irradiated were removed in the thin films so that the thin films were positive-tone patterned to have square shapes with 5 μm each side in FIG. 4A, 10 μm each side in FIG. 4B, 20 μm each side, and 50 μm each side in FIG. 4C, respectively. When the molar ratio of tBPMTES:BTESE:triethoxysilylphenol in Experimental Example 4 was 40%:30%:30%, the hardness of the thin film measured using a nanoindenter was 2.396 GPa, and its modulus of elasticity was 58.239 GPa. Considering that the hardness required to endure a chemical mechanical polishing (CMP) process is typically about 1 GPa, it may be seen that the hardness of the thin film was significantly increased, e.g., about 2.4-fold compared to a typical thin film.

### EXPERIMENTAL EXAMPLE 5

### Terpolymer 2 and Thin Film

Nitrogen gas was flowed into reaction vessels with a refluxing device to form an atmosphere having a pressure of 1 atm. The first monomer, whose R is an ethyl group, R₂ is a methylene group, and R₃ is a t-butoxycarbonyl group in Chemical Formula 2, the second monomer BTESE, whose Z₁ to Z₆ are each ethoxy groups and A₁ is an ethylene group in Chemical Formula 5, and the third monomer triethoxysilylphenol whose R₇ is an ethyl group and n is zero in the General Formula 1: (R₇O)₃—Si—C₆H₄—(C(R₈)₂)ₙ—OH, for improving an adhesion property, were added to the reaction vessel in a molar ratio of 40%:30%:30%, respectively. THF as a solvent was then added to the vessel in an amount such that the total concentration of the three monomers was 25 wt % based on the total weight of the solvent and the monomers. Tetrabutylammonium hydroxide as a base catalyst was then added in a 1:0.1 molar ratio of the three monomers to the tetrabutylammonium hydroxide. Water was added in a 1:4 molar ratio of the three monomers to the water. The reaction vessel was then subjected to reaction at 60° C. for 10 hours. All solvents were removed after the reaction to obtain a solid-state polysilsesquioxane copolymer. Measured Mn and M_{w} of the terpolymer were 8400 and 12000, respectively.

A photoacid generator, Ciba IRGACURE 1XX series made by Ciba Co., was added in an amount of 6 wt % based on the total weight of the copolymer and the photoacid generator to each of the solid-state copolymer. PM acetate as an organic solvent in an amount of 25 wt % based on the total weight of the copolymer and the photoacid generator was injected into the reaction vessel, and then subjected to mixing. After mixing, the solution was spin-coated on a substrate at 3000 rpm for 30 seconds to have a thickness of 750 nm, and then baked for 1 minute at 100° C.

FIG. 5 illustrates an AFM image of the thin film according to Experimental Example 5. Referring to FIG. 5, it may be seen that the hardness of the thin film according to Experimental Example 5 was measured to have a good surface property. In addition, the hardness of the thin film according to Experimental Example 5 measured using a nanoindenter was 1.335 GPa, and its modulus of elasticity was 53.963 GPa. Considering that the hardness required to endure a CMP process is typically about 1 GPa, it may be seen that the hardness of the thin film according to Experimental Example 5 significantly exceeds the 1 GPa value.

UV rays having center wavelengths of 365 nm, and projected in a square or straight line shape, were irradiated onto each of the thin films, and the thin films were exposed to light and baked for 2 minutes at 110° C. The thin films were then developed by being immersed in 2.38 wt % TMAH water solution for 20 seconds, rinsed in DI water for 20 seconds, and cured for 60 minutes at 230° C.

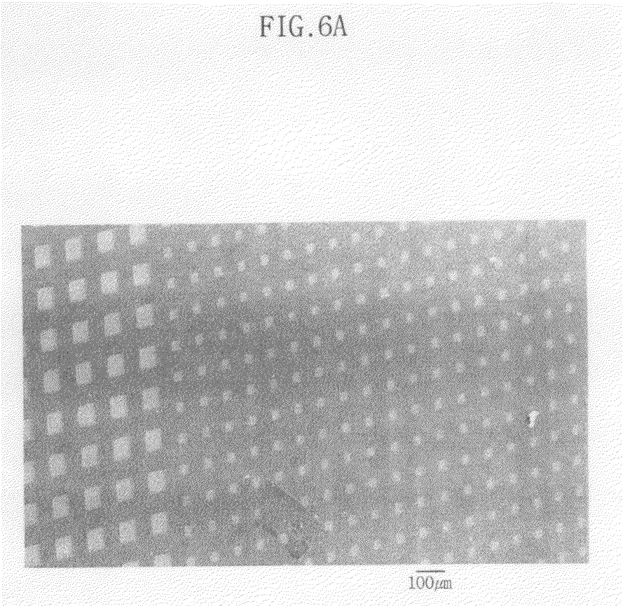

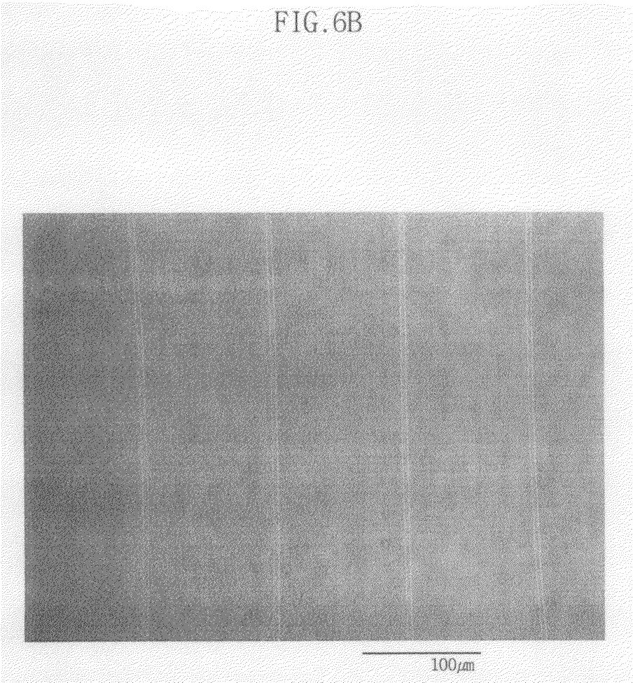

FIGS. 6A and 6B illustrate pictures of the positive-tone patterned thin films described above. Referring to FIG. 6A, it may be seen that the thin film was positive-tone patterned to have a square shape. In addition, referring to FIG. 6B, it may be seen that a portion where a straight line-shaped laser was irradiated was removed and a thin solid line where the laser was not irradiated remained and was positive-tone patterned.

According to the embodiments, a thin film fabricated using a polysilsesquioxane copolymer may have good mechanical strength and planarization performance, and may allow positive-tone patterning to be carried out by directly irradiating light, without using a PR. In addition, when a planarization layer of an OLED display device is formed using the thin film, source and drain electrodes 161 and 162 below the planarization layer may be effectively protected and the process may be simplified when a via hole is formed in the planarization layer.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A polysilsesquioxane copolymer, comprising:
a copolymer including:
repeating units derived from a first monomer selected from the group consisting of compounds represented by Chemical Formulae 1 to 4: 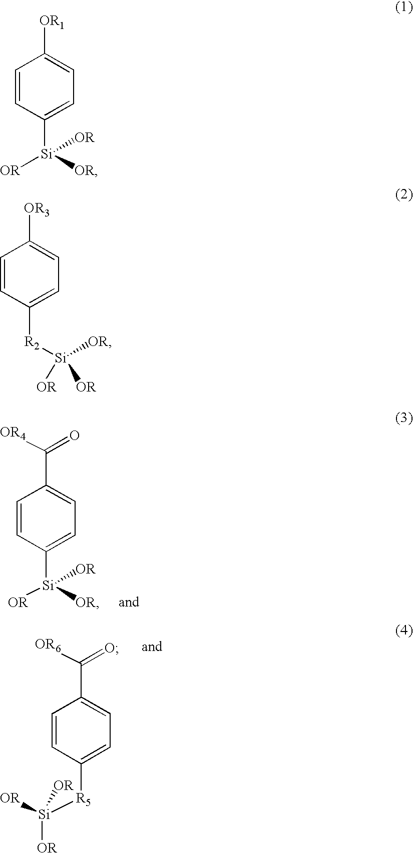
repeating units derived from a second monomer including an α,ω-bis(trialkoxysilyl) compound monomer represented by Chemical Formula 5: 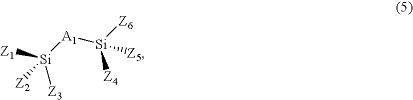
wherein in Chemical Formulae 1 to 4, R, R₁, R₂, R₃, R₄, R₅, and R₆ are each independently a substituted or unsubstituted C₁ to C₃₀ alkyl group, and in Chemical Formula 5, Z₁, Z₂, Z₃, Z₄, Z₅, and Z₆ are each independently a hydroxy group, a substituted or unsubstituted C₁ to C₃₀ alkyl group, or a substituted or unsubstituted C₁ to C₃₀ alkoxy group, and A₁ is a substituted or unsubstituted C₁ to C₃₀ alkyl residue.

2. The polysilsesquioxane copolymer as claimed in claim 1, wherein the copolymer further includes:
repeating units derived from a third monomer selected from the group consisting of compounds represented by:
General Formula 1: (R₇O)₃—Si—C₆H₄—(C(R₈)₂)ₙ—OH, and
General Formula 2: (R₇O)₃—Si—C₆H₄—(C(R₈)₂)ₙ—COOH,
wherein, in General Formulae 1 and 2, R₇ and R₈ are each independently a hydrogen or alkyl group, and n is 0 to 10.

3. The polysilsesquioxane copolymer as claimed in claim 2, wherein the polysilsesquioxane copolymer has a weight average molecular weight of about 900 to about 30000.

4. The polysilsesquioxane copolymer as claimed in claim 2, wherein the repeating units derived from the third monomer are included in a molar ratio of greater than 0 to about 50% based on the total moles of the first monomer and the second monomer repeating units.

5. The polysilsesquioxane copolymer as claimed in claim 1, wherein the polysilsesquioxane copolymer has a weight average molecular weight of about 900 to about 30000.

6. The polysilsesquioxane copolymer as claimed in claim 1, wherein the repeating units derived from the first monomer and the repeating units derived from the second monomer are included in a molar ratio of about 50 to less than 100% of the first monomer repeating units:greater than 0 to less than about 50% of the second monomer repeating units.

7. A polysilsesquioxane copolymer thin film, comprising:
a photoacid generator, and
the polysilsesquioxane copolymer as claimed in claim 1.

8. The polysilsesquioxane copolymer thin film as claimed in claim 7, wherein the photoacid generator includes at least one of arylbis(trichloromethyl)triazine and enferfluorobutane sulfonyl naphthalenin imide.

9. The polysilsesquioxane copolymer thin film as claimed in claim 7, wherein the photoacid generator is included in an amount of about 1 to about 30 wt % based on the total weight of the polysilsesquioxane copolymer and the photoacid generator.

10. The polysilsesquioxane copolymer thin film as claimed in claim 7, wherein portions of the thin film exposed to UV light are soluble in a developing solution of tetramethylammonium hydroxide (TMAH).

11. An organic light emitting diode display device, comprising:
a substrate;
a thin film transistor (TFT) disposed on the substrate and including a semiconductor layer, a gate electrode, a gate insulating layer, and source and drain electrodes;
a planarization layer disposed on the TFT; and
an organic light emitting diode disposed on the planarization layer and including a first electrode electrically connected to the source or drain electrode, an organic layer having an emitting layer, and a second electrode,
wherein the planarization layer includes the polysilsesquioxane copolymer thin film as claimed in claim 7.

12. A polysilsesquioxane copolymer thin film, comprising:
a photoacid generator, and
the polysilsesquioxane copolymer as claimed in claim 2.

13. The polysilsesquioxane copolymer thin film as claimed in claim 12, wherein the photoacid generator is included in an amount of about 1 to about 30 wt % based on the total weight of the polysilsesquioxane copolymer and the photoacid generator.

14. The polysilsesquioxane copolymer thin film as claimed in claim 12, wherein portions of the thin film exposed to UV light are soluble in a developing solution of tetramethylammonium hydroxide (TMAH).

15. The polysilsesquioxane copolymer thin film as claimed in claim 12, wherein the photoacid generator includes at least one of arylbis(trichloromethyl)triazine and enferfluorobutane sulfonyl naphthalenin imide.

16. An organic light emitting diode display device, comprising:
a substrate;
a thin film transistor (TFT) disposed on the substrate and including a semiconductor layer, a gate electrode, a gate insulating layer and source and drain electrodes;
a planarization layer disposed on the TFT; and
an organic light emitting diode disposed on the planarization layer and including a first electrode electrically connected to the source or drain electrode, an organic layer having an emitting layer, and a second electrode,
wherein the planarization layer includes the polysilsesquioxane copolymer thin film as claimed in claim 12.

17. A method of fabricating a polysilsesquioxane copolymer, comprising:
copolymerizing, using an acid or base catalyst in a mixed solvent including an organic solvent and water, a first monomer selected from the group consisting of compounds represented by Chemical Formulae 1 to 4: 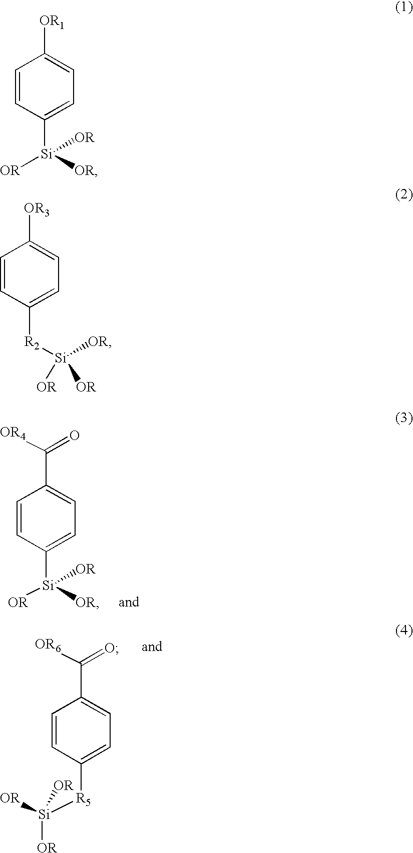
a second monomer including an α,ω-bis(trialkoxysilyl) compound monomer represented by Chemical Formula 5: 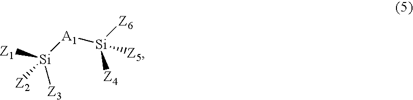
wherein in Chemical Formulae 1 to 4, R, R₁, R₂, R₃, R₄, R₅ and R₆ are each independently a substituted or unsubstituted C₁ to C₃₀ alkyl group, and in Chemical Formula 5, Z₁, Z₂, Z₃, Z₄, Z₅ and Z₆ are each independently a hydroxy group, a substituted or unsubstituted C₁ to C₃₀ alkyl group, or a substituted or unsubstituted C₁ to C₃₀ alkoxy group, and A₁ is a substituted or unsubstituted C₁ to C₃₀ alkyl residue.

18. The method as claimed in claim 17, wherein the first monomer and the second monomer are included in a molar ratio of about 50 to less than 100% of the first monomer:greater than 0 to less than about 50% of the second monomer.

19. The method as claimed in claim 17, further comprising copolymerizing a third monomer selected from the group consisting of compounds represented by:
General Formula 1: (R₇O)₃—Si—C₆H₄—(C(R₈)₂)ₙ—OH, and
General Formula 2: (R₇O)₃—Si—C₆H₄—(C(R₈)₂)ₙ—COOH,
wherein, in General Formulae 1 and 2, R₇ and R₈ are each independently a hydrogen or alkyl group, and n is 0 to 10.

20. The method as claimed in claim 19, wherein the third monomer is included a molar ratio of greater than 0 to about 50% based on the total moles of the first monomer and the second monomer.
